(19) United States
(12) Patent Application Publication
(10) Pub. No.: US 2009/0174073 A1
(43) Pub. Date: Jul. 9, 2009

(54) SUBSTRATE FOR SEMICONDUCTOR PACKAGE HAVING COATING FILM AND METHOD FOR MANUFACTURING THE SAME

(76) Inventor: Woong Sun LEE, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/254,884

(22) Filed: Oct. 21, 2008

(30) Foreign Application Priority Data
Jan. 8, 2008 (KR) 10-2008-0002252

(51) Int. Cl. H01L 23/52; H01L 21/00

(52) U.S. Cl. 257/738; 438/121; 257/E23.141; 257/E21.001

(57) ABSTRACT

A substrate for a semiconductor package includes a ball land disposed on one surface of an insulating layer. A solder resist is applied to the surface of insulating layer while leaving the ball land exposed. A coating film is applied on the exposed surface of the 1o ball land. The coating film includes a high molecular compound having metal particles. In the substrate having the ball land with the coating film formed thereon, it is not necessary to subject the substrate to a UBM formation process.

### CROSS-REFERENCE TO RELATED APPLICATIONS

The present application claims priority to Korean patent application number 10-2008-0002252 filed on Jan. 8, 2008, which is incorporated herein by reference in its entirety.

### BACKGROUND OF THE INVENTION

The present invention relates generally to a substrate for a semiconductor package and a method for manufacturing the same, and more particularly, to a substrate having a ball land for a semiconductor package and a method for manufacturing the same. [0003] In the semiconductor industry, the demand for miniaturization and the need for mounting reliability have provided a constant driving force for improvements in integrated circuit packaging technology. For example, the demand for miniaturization has accelerated technological development to the point where the size of semiconductor packages is getting close to being no more than the size of the chip itself. The necessity of mounting reliability is underlined by the importance of packaging technology that can improve the efficiency of mounting works and the mechanical and electrical reliability after mounting.

A Ball Grid Array (BGA) package is one example of a miniaturized package. The advantages of the BGA package include that its overall size is the same or very near to the same as the size of the semiconductor chip, and also that the mounting area tends to be reduced since a solder ball provides a means to which an electric connection means (e.g., a printed circuit board (PCB) that provides an electrical connection to the outside) is mounted.

Further, the BGA package allows the overall length of the electric circuit to be reduced; and additionally, in the BAG package a power or ground bonding area can be easily introduced simply by 1o using a printed circuit board as a means of providing an electrical connection to the outside. Therefore, it is possible to obtain a superior electric performance when utilizing a BAG package. In addition, the BGA package can provide a larger number of input/output pins at a wider distance than designed.

Hereinafter, a conventional BGA package will be described.

A semiconductor chip is attached to a substrate equipped with an electrode terminal, and the semiconductor chip and the substrate are electrically connected to each other via a bonding wire. The top surface of the substrate, the bonding wire, and the semiconductor chip are sealed using a sealant such as an Epoxy Molding Compound (EMC) in order to protect the semiconductor chip from external stresses. A solder ball is attached to a ball land allocated on the bottom surface of the substrate. The solder ball attached to the ball land provides an external connection terminal.

In more detail, the solder ball is attached to the ball land 108 after forming a thin metal film 114 of several layers, which is also known as under bump metallurgy (UBM). The thin metal film consists of Nickel 110 and gold 112 on a copper interface of the ball land as shown in FIG. 1.

A solder ball is very vulnerable to the diffusion of copper ions therein. The above-mentioned UBM formed on the ball land prevents copper ions in the ball land from diffusing into the solder ball and the bonding surface.

A method for fabricating UBM consisted of a thin metal film such as nickel and gold is as follows.

The substrate having the copper ball land is primarily cleaned in a plating tub excessively saturated with palladium. The primarily cleaned substrate is immersed in a plating tub containing an excessive amount of nickel in order to form a nickel layer on the ball land. The substrate having the nickel layer is subjected to a secondary cleaning, and the secondary cleaned substrate is immersed in a gold plating tub in order to form a gold layer on the nickel layer. The substrate having the gold layer is then subjected to a third cleaning.

The process cost of the plating process mentioned above is high and includes a several step photo-process for forming the plating layer in a laminating layer. The steps cause an increase in the failure rate of the package. Therefore, the plating process requires a considerable amount of technology for improving the process reliability in order to prevent the high failure rate.

Further, the plating process must be performed repeatedly within the plating tub in order to plate nickel and gold, and the plating solution and the plating tub can be contaminated causing a thickness of the plating layer to vary irregularly. The plating process can cause both plating failure, and a failure in that the solder ball is not well bonded due to breakage of the plating layer and irregular plating of the plating layer.

Further, the integrity of the plating layer is highly reliant on any minute changes in the conditions of the plating tub and changes in the compositions of the plating solutions; and therefore, the plating layer becomes irregular if the conditions of the plating tub and/or the compositions of the plating solutions vary.

Therefore, due to the possibility of the numerous failures mentioned above, the substrate for the BGA package formed by the plating process causes the overall production cost of the package to increase when manufacturing the semiconductor package.

### SUMMARY OF THE INVENTION

Embodiments of the present invention include a substrate for a semiconductor package capable of reducing failure rate and improving reliability and a method for manufacturing the same.

Further, embodiments of the present invention provide a substrate for a semiconductor package capable of minimizing the number of overall process steps and the production costs by reducing failure rate and improving reliability.

In one aspect, a substrate for a semiconductor package according to the present invention includes an insulating layer; a ball land disposed on one surface of the insulating layer; a solder resist applied on the one surface of the insulating layer such that the ball land is exposed; a coating film applied on a surface of the ball land exposed; and a solder ball attached on the ball land to which the coating film is applied.

The coating film comprises a high molecular compound containing metal particles.

The high molecular compound comprises a polymer and a compound using thermoplastic resin or thermosetting resin as a base.

The percentage of the metal particles is in the range of 0.1 to 40% of the overall amount of the high molecular compound.

The metal particle comprises any one of a Ni, Al, Ag, Fe, Cu and Au particle.

The size of the metal particle is in the range of 0.1 to 1 μm.

The thickness of the coating film is in the range of 0.1 to 100 μm.

In another aspect, a method for manufacturing a substrate for a semiconductor package according to the present invention includes the steps of applying a solder resist on one surface of an insulating layer such that a ball land is exposed; applying a coating film to the exposed surface of the ball land; and attaching a solder ball on the ball land to which the coating film is applied.

The coating film comprises a high molecular compound containing metal particles.

The high molecular compound comprises a polymer and a compound using thermoplastic resin or thermosetting resin as a base.

The percentage of the metal particles is in a range of 0.1 to 40% of an overall amount of the high molecular compound

The metal particle comprises any one of a Ni, Al, Ag, Fe, Cu and Au particle.

The metal particle is formed to be a size in the range of 0.1 to 1 μm.

The coating film is applied at a thickness in a range of 0.1 to 100 μm.

The step of applying the coating film is performed in a spray method or an immersing method.

The immersing manner is performed for 5˜15 seconds.

A curing process is performed after applying the coating film in the immersing method.

The curing process is performed at a temperature in the range of 70 to 90° C. for 25˜35 minutes.

### BRIEF DESCRIPTION OF THE DRAWINGS

FIG. 1 is a cross-sectional view shown for illustrating the problems of the prior art.

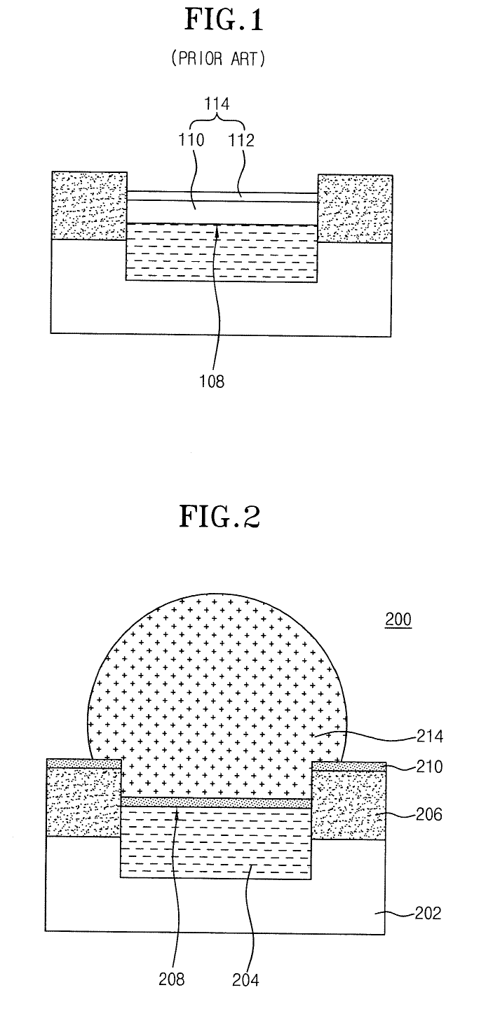

FIG. 2 is a cross-sectional view showing a substrate for a semiconductor package according to one embodiment of the present invention.

FIGS. 3a to 3c are cross-sectional views shown for lo illustrating the steps in a method for manufacturing a substrate for a semiconductor package according to one embodiment of the present invention.

FIG. 4 is a cross-sectional view showing a method for manufacturing a substrate for a semiconductor package according to another embodiment of the present invention.

### DESCRIPTION OF SPECIFIC EMBODIMENTS

A substrate for a semiconductor package according to the present invention includes a ball land to which a solder ball is attached and a coating film which is applied on the ball land and consists of a high molecular compound containing metal particles, wherein the solder ball is attached on the ball land to which the coating film is applied.

The present invention does not require a UBM formation process when forming the coating film, as compared to the prior art, which requires the formation of UBM consisting of nickel and gold to compensate for the vulnerability of the solder ball.

Therefore, embodiments of the present invention can reduce failure rate of a package caused by several photo-process steps used for forming UBM, and therefore the present invention improves process reliability.

Further, embodiments of the present invention, which include the coating film for attaching a solder ball, do not require a prior plating process (i.e., UBM formation process), and therefore it is possible to prevent an oxidation phenomenon of copper from occurring, and it is possible to prevent breakage and irregular plating of the plating layer; and therefore, it is possible to prevent failure caused when the solder ball is not well bonded.

Embodiments of the present invention can decrease the number of overall process steps and can prevent an increase in the production costs when producing the substrate for a semiconductor package.

Hereinafter, a preferred embodiment of the present invention will be described in detail with reference to the accompanying drawings.

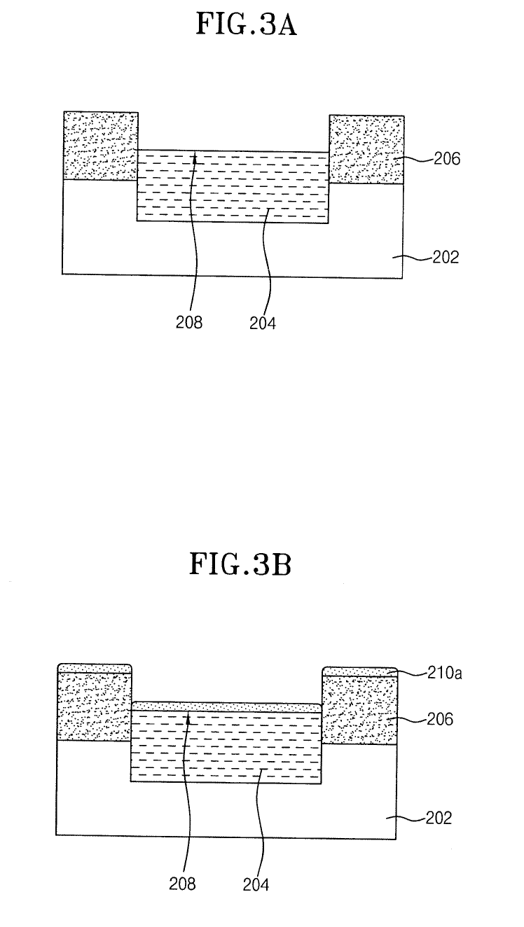

FIG. 2 is a cross-sectional view showing a substrate for a semiconductor package according to an embodiment of the present invention.

As shown in FIG. 2, a substrate 200 for a semiconductor package according to one embodiment of the present invention has a ball land 208 disposed on a surface thereof. The insulating layer includes circuit wiring 204 comprising copper, and a solder resist 206 is applied to the insulating layer 202 having the circuit wiring 204. The solder resist 206 is formed such that the ball land 208 is exposed.

A coating film 210 is formed on the solder resist 206 and the ball land 208 of the insulating layer 202. The coating film 210 has a thickness in the range of 0.1 to 100 μm. A solder ball is attached to the ball land 208 on which the coating film 210 is formed, and the solder ball functions as an external connection terminal 214.

The coating film 210 consists of a high molecular compound containing metal particles. The high molecular compound consists of a polymer and a compound using thermoplastic or thermosetting resin as a base. The metal particle has a size in the range of 0.1 to 1 μm. Further, the metal particle consists of any one of an Ni, Al, Ag, Fe, Cu, and Au particle containing a large amount of polyethylene or epoxy materials. The percentage of the metal particles contained within the total high molecular compound is in the range of 0.1 to 40%.

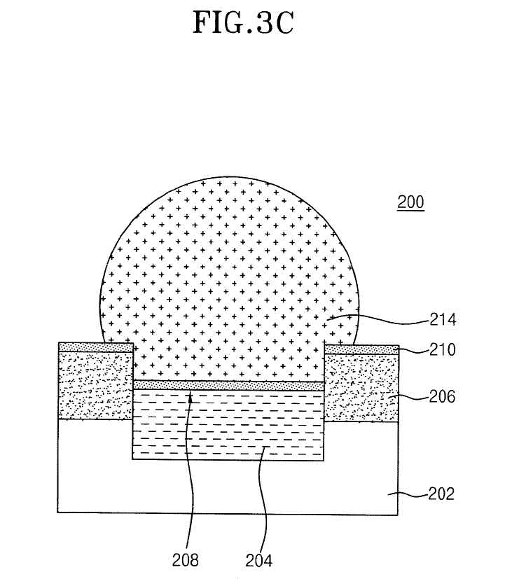

FIGS. 3a to 3c are cross-sectional views shown for illustrating the steps in a method for manufacturing a substrate for a semiconductor package according to one embodiment of the present invention.

Referring to FIG. 3a, an insulating layer 202 having a ball land 208 disposed on one surface and including a circuit wiring 204 consisting of copper is provided. A solder resist 206 is applied to the insulating layer such that the ball land 208 is exposed.

Referring to FIG. 3b, a high molecular compound 210a containing metal particles is disposed on the ball land 208 (which is left exposed by the solder resist 206) and the solder resist 206 of the insulating layer 202. The high molecular compound 210a is applied using an aerosol-type spray method.

The high molecular compound 210a consists of a polymer and a compound using thermoplastic resin or thermosetting resin as a base. The metal particle contained in the high molecular compound has a size in the range of 0.1 to 1 μm, and the metal particle consists of any one of an Ni, Al, Ag, Fe, Cu and Au particle containing a large amount of polyethylene or epoxy materials. The percentage of the metal particles contained within the total high molecular compound 210a is in the range of 0.1 to 40%, and preferably in the range of 1 to 30%.

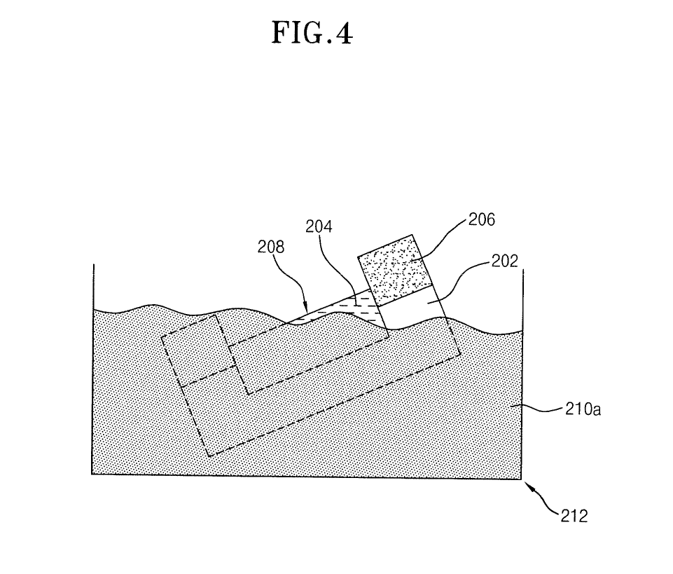

As an alternative to the above-mentioned spray method, the high molecular compound 210a can also be formed by immersing the substrate 202 into a tub 212 including the high molecular compound 210a to which any one particle comprising Ni, Al, Ag, Fe, Cu and Au particle is added as is shown in FIG. 4.

The immersing method is performed for 5˜15 seconds. The high molecular compound 210a is applied to the substrate 202 by the immersion, and then is cured at a temperature in the range of 70° C. to 90° C. for 25˜35 minutes.

Referring to FIG. 3c, a solder ball functioning as an external connection terminal 214 is attached to the ball land 208 (which includes the coating film 210 formed using the aerosol-type spray method or the immersing method) to complete the manufacturing process of the substrate 200 for the semiconductor package according to one embodiment of the present invention.

As mentioned earlier, it is possible to omit a UBM formation process by instead applying a coating film consisting of a high molecular compound containing metal particles to the ball land to which a solder ball is going to be attached.

Therefore, the present invention allows for a reduction in package failure rate (which is induced by a photo-process taking several steps for forming UBM), and thereby the present invention can improve process reliability.

Further, according to the present invention, a plating process (i.e., UBM formation process) is not necessary since a solder ball is attached using the coating film, and thereby both an oxidation phenomenon of copper and breakage and/or irregular plating of the plating layer are prevented, which results in the prevention of failures caused when a solder is not well bonded.

Accordingly, the present invention can reduce the number of overall process steps required and can also reduce the production costs of manufacturing a substrate for a semiconductor package.

Although specific embodiments of the present invention have been described for illustrative purposes, those skilled in the art will appreciate that various modifications, additions and substitutions are possible without departing from the scope and the spirit of the invention as disclosed in the accompanying claims.

What is claimed is:

1. A substrate for a semiconductor package, comprising:
an insulating layer;
a bail land disposed on a surface of the insulating layer;
a solder resist disposed on the surface of the insulating layer such that the ball land is exposed;
a coating film disposed on at least a surface of the exposed ball land; and
a solder ball attached on the ball land to which the coating film is applied.

2. The substrate for the semiconductor package according to claim 1, wherein the coating film comprises a high molecular compound, the high molecular compound comprising metal particles.

3. The substrate for the semiconductor package according to claim 2, wherein the high molecular compound comprises a polymer and a compound using thermoplastic resin or thermosetting resin as a base.

4. The substrate for the semiconductor package according to claim 2, wherein the percentage of the metal particles is in the range of 0.1 to 40% of the overall amount of the high molecular compound.

5. The substrate for the semiconductor package according to claim 2, wherein the metal particle comprises any one of Ni, Al, Ag, Fe, Cu, and Au.

6. The substrate for the semiconductor package according to claim 2, wherein the size of the metal particle is in the range of 0.1 to 1 μm.

7. The substrate for the semiconductor package according to claim 1, wherein the thickness of the coating film is in the range of 0.1 to 100 μm.

8. A method for manufacturing a substrate for a semiconductor package, comprising steps of:
providing an insulating layer having a surface on which a ball land is disposed;
applying a solder resist to the surface of the insulating layer such that the ball land is exposed;
applying a coating film to a surface of the exposed ball land; and
attaching a solder ball on the ball land to which the coating film is applied.

9. The method according to claim 8, wherein the coating film comprises a high molecular compound, the high molecular compound comprising a metal particle.

10. The method according to claim 9, wherein the high molecular compound comprises a polymer and a compound using thermoplastic resin or thermosetting resin as a base.

11. The method according to claim 9, wherein the percentage of the metal particles is in the range of 0.1 to 40% of the overall amount of the high molecular compound

12. The method according to claim 9, wherein the metal particle comprises any one of Ni, Al, Ag, Fe, Cu and Au.

13. The method according to claim 9, wherein the metal particle is formed such that the size of the metal particle is in the range of 0.1 to 1 μm.

14. The method according to claim 9, wherein the coating film is applied such that the thickness of the coating film is in the range of 0.1 to 100 μm.

15. The method according to claim 10, wherein the step of applying the coating film is performed using a spray method or an immersing method.

16. The method according to claim 15, wherein the immersing method is used, and the substrate is immersed for 5˜15 seconds.

17. The method according to claim 15, wherein the immersing method is used, and after the substrate has been immersed a curing process is performed.

18. The method according to claim 17, wherein the curing process is performed at a temperature in the range of 70° C. to 90° C. for 25˜35 minutes.
